(19) United States
(12) Patent Application Publication
(10) Pub. No.: US 2013/0269601 A1
(43) Pub. Date: Oct. 17, 2013

(54) GRAPHITE HEATER

(71) Applicant: IBIDEN CO., LTD., Ogaki-shi (JP)

(72) Inventors: Kazutaka MAJIMA, Ogaki-shi (JP); Eita IYOSHI, Ogaki-shi (JP)

(73) Assignee: IBIDEN CO., LTD., Ogaki-shi (JP)

(21) Appl. No.: 13/858,251

(22) Filed: Apr. 8, 2013

(30) Foreign Application Priority Data
Apr. 13, 2012 (JP) 2012-091719

(51) Int. Cl. H05B 3/14; H05B 3/42; C30B 15/14

(52) U.S. Cl. CPC H05B 3/145; C30B 15/14; H05B 3/42
USPC 117/217; 219/553

(57) ABSTRACT

A graphite heater includes a main body, and a plurality of support portions. The main body includes a tubular portion and a plurality of terminal portions. The plurality of terminal portions extend outward along a central axis of the tubular portion. Each of the plurality of terminal portions has a first planar surface facing the central axis or facing an opposite side of the central axis. The plurality of support portions are each joined to each of the plurality of terminal portions. Each of the plurality of support portions has a second planar surface. The first planar surface and the second planar surface are joined through a carbon-based adhesion layer.

### CROSS-REFERENCE TO RELATED APPLICATIONS

The present application claims priority under 35 U.S.C. §119 to Japanese Patent Application No. 2012-91719, filed Apr. 13, 2012. The contents of this application are incorporated herein by reference in their entirety.

### BACKGROUND OF THE INVENTION

1. Field of the Invention

The present invention relates to a graphite heater.

2. Discussion of the Background

As a fixing structure of a graphite heater, “a fixing structure of a graphite heater in which, in the graphite heater that is disposed around a crucible rotating with respect to a base table and heats the crucible, the bottom end of the graphite heater is fixed to a fixing member that fixes the graphite heater to the top side of the base table through a carbonized or graphitized adhesion layer” is disclosed (JP-UM-A-3-53791).

In addition, in JP-UM-A-3-53791, as an industrial application, a fixing structure of a graphite heater, which is used in a silicon single crystal pull-up apparatus, for which the Czochralski method is used, in order to melt a silicon raw material in a crucible, is disclosed.

### SUMMARY OF THE INVENTION

According to one aspect of the present invention, a graphite heater includes a main body, and a plurality of support portions. The main body includes a tubular portion and a plurality of terminal portions. The plurality of terminal portions extend outward along a central axis of the tubular portion. Each of the plurality of terminal portions has a first planar surface facing the central axis or facing an opposite side of the central axis. The plurality of support portions are each joined to each of the plurality of terminal portions. Each of the plurality of support portions has a second planar surface. The first planar surface and the second planar surface are joined through a carbon-based adhesion layer.

### BRIEF DESCRIPTION OF THE DRAWINGS

A more complete appreciation of the invention and many of the attendant advantages thereof will be readily obtained as the same becomes better understood by reference to the following detailed description when considered in connection with the accompanying drawings.

FIG. 1 is a perspective view illustrating an example of a graphite heater of the invention.

FIGS. 2A and 2B illustrate front views schematically illustrating terminal portions of the graphite heater of FIG. 1.

FIGS. 3A and 3B illustrate plan views schematically illustrating main body portions of the graphite heater of FIG. 1.

FIG. 4 is an explanatory view illustrating a joining method of the terminal portion and a support portion of the graphite heater of FIG. 1.

FIG. 5 is an explanatory view illustrating a joining state of the terminal portion and the support portion of the graphite heater of FIG. 1.

FIG. 6 is a plan view of a graphite heater of Embodiment 1 of the invention.

FIG. 7 is a front view of the graphite heater of Embodiment 1 of the invention.

FIG. 8 is a cross-sectional view of the graphite heater of Embodiment 1 of the invention.

FIG. 9 is a plan view of a main body of the graphite heater of Embodiment 1 of the invention.

FIG. 10 is a front view of the main body of the graphite heater of Embodiment 1 of the invention.

FIG. 11 is an explanatory view illustrating the dimensions of the main body of the graphite heater of Embodiment 1 of the invention.

FIG. 12 is a plan view illustrating a first modification example of the main body of the graphite heater of Embodiment 1 of the invention.

FIG. 13 is a plan view illustrating a second modification example of the main body of the graphite heater of Embodiment 1 of the invention.

FIG. 14 is a plan view illustrating a second modification example of the main body of the graphite heater of Embodiment 1 of the invention.

### DESCRIPTION OF THE EMBODIMENTS

According to an embodiment of the present invention,

(1) A graphite heater includes,

a tubular main body portion, a plurality of terminal portions extending outward along a central axis of the tubular main body portion, and support portions that are joined to the terminal portions,

in which a first planar surface facing the central axis or an opposite side of the central axis is formed in the tubular main body portion, a second planar surface is formed in the support portion, and

the first planar surface and the second planar surface are joined through a carbon-based adhesion layer.

(2) A plurality of the support portions are provided around the central axis as an axis of rotation symmetry.

(3) The first planar surface faces a side of the central axis, and a distance between the first planar surface and the side of the central axis becomes smallest at a center of the first planar surface.

(4) The tubular main body portion has a heat generating portion, in which slits are formed, and a minimum value of a distance between the first planar surface and the central axis is smaller than a radius of an inner surface of the heat generating portion.

(5) In the above graphite heater, the support portions and the main body portion are further connected using bolts which penetrate the adhesion layer and are made of carbon.

(6) The above graphite heater is used in a silicon single crystal pull-up apparatus.

In recent years, an attempt has been made to increase the size of a silicon single crystal pull-up apparatus as the size of a silicon wafer increases. In addition, since the size and length of a silicon ingot have been increased, the time from the beginning to the end of lifting of a single crystal has also extended.

The above facts caused the following problems.

(1) Since the size of the apparatus has increased, the difference in thermal expansion between a chamber and a hot zone, which compose an outer shell of the apparatus, increases. The difference in thermal expansion causes stress in the periphery of a support portion that connects a main body of a graphite heater, which is a heat generating area, at which the temperature becomes highest, and an electrode terminal that is connected to the chamber cooled through an insulating member, such as an insulator. The value of stress generated due to the above action increases as the size of the apparatus increases.

(2) When the size of the apparatus increases, the mass of a member, such as the graphite heater, increases in proportion to the third power of the size of the apparatus. In contrast to the above, the area of a support part that receives the member increases in proportion to the square of the size of the apparatus. Therefore, stress applied to an adhesion layer of the graphite heater, which employs the fixing structure (adhering structure) described in Patent Document 1, increases at an accelerating pace as the size of the apparatus increases.

(3) Since the time from the beginning to the end of lifting of a single crystal extends, the probability of the occurrence of problems, such as breaking and spark, in a connection part between a main body portion and the support portion of the graphite heater during a single cycle from the beginning of lifting to the end of lifting. In addition, since the time from the beginning to the end of lifting of a single crystal has extended, it becomes difficult to predict the occurrence of problems in the graphite heater before the beginning of lifting, and it becomes difficult to set a long replacement cycle of the heater.

The embodiments of the invention provides a graphite heater having a joining structure between the terminal portion and the support portion, which has favorable joining strength and durability, and is advantageous for an increase in the size.

According to the embodiments of the present invention, the first planar surfaces, which are parallel to the central axis, and the second planar surfaces of the support portions are connected to a plurality of the terminal portions extending outward along the central axis. Therefore, when end portions are extended, it is possible to freely increase the area of the adhesion layer, and to decrease stress applied to the adhesion layer.

In addition, since the adhesion layer made of carbon or graphite is formed by firing or graphitizing an adhesive including an organic substance, the dimensions are shrunk during firing or graphitizing. Therefore, when the thickness of the adhesive layer is uneven in a step for coating the adhesive including an organic substance, voids are generated in thick portions during firing or graphitizing such that the strength decreases. According to the embodiments of the present invention, since all the surfaces that are joined to the adhesion layer are planar surfaces, it is possible to decrease the variation in the thickness of the adhesion layer, which is caused by machining errors. Therefore, it is possible to make the entire adhesion layer uniformly shrink, and to prevent the easy formation of voids. Therefore, the adhesion strength can be increased.

Furthermore, since the embodiments of the present invention has the adhesion layer between the first planar surface and the second planar surface, the atmosphere gas in a furnace cannot easily intrude into the portion at which the first planar surface and the second planar surface come into contact so that it is possible to prevent a decrease in the thickness which may cause easy breaking, an increase in the contact resistance, abnormal heat generation, and spark due to a reaction, such as the oxidation or silication of the first planar surface and the second planar surface.

For the above reasons, it is possible to provide a joining structure between the main body portion and the support portion in a graphite heater for lifting a silicon single crystal, which has favorable joining strength and durability, and is advantageous for an increase in the size.

The embodiments will now be described with reference to the accompanying drawings, wherein like reference numerals designate corresponding or identical elements throughout the various drawings.

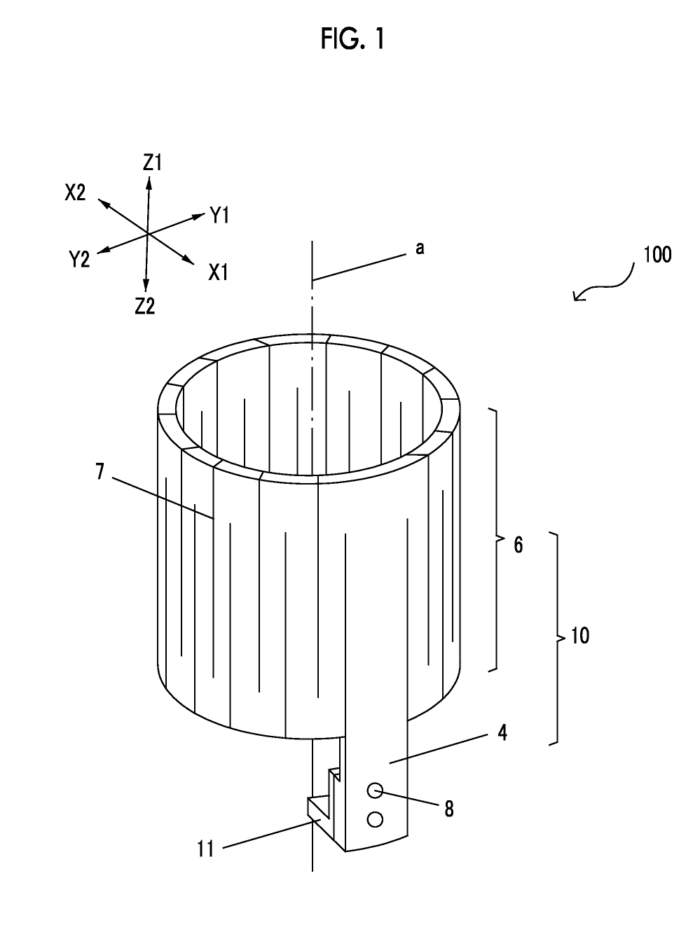

First, the definitions of the directional properties of the graphite heater will be described for description. As illustrated in FIG. 1, in the tubular main body portion, a central axis a of the tube is defined to be in a z1-z2 direction (z axis), in which z1 indicates the upper direction. The direction of a specific terminal portion from the central axis a is defined as an x1 direction (x axis). The y axis is at a right angle to both the x axis and the z axis. For example, in a case in which the graphite heater symmetrically has two terminal portions, the terminal portions are located in the x1 and x2 directions from the central axis a, and, in a case in which the graphite heater symmetrically has four terminal portions 4, the terminal portions are located in the x1, x2, y1 and y2 directions from the central axis a respectively.

In the embodiments of the present invention, isotropic graphite, extruded graphite, molded graphite and the like can be used as the graphite.

The isotropic graphite is obtained by carrying out cold isostatic pressing (CIP) on raw material powder made up of coke and a binder, then, firing and graphitizing the raw material powder. The isotropic graphite is also called a CIP graphite material, special carbon or the like. Since the isotropic graphite material is molded through cold isostatic pressing, the characteristics of the material are not easily anisotropic, and, for example, a material having an anisotropy ratio of intrinsic resistance or thermal expansion coefficient of approximately 1.3 or less can be easily obtained. Examples of the isotropic graphite material that can be used include ET-10, T-4, T-5 and the like, which are manufactured by Ibiden Co., Ltd.

The extruded graphite is obtained by extruding raw material powder made up of coke and a binder, and, similarly, firing and graphitizing the raw material powder. During extrusion, the hexagonal net surfaces of graphite crystals are liable to be arranged in the extrusion direction, and the intrinsic resistance and thermal expansion coefficient become smallest in the extrusion direction. An extruded electrode is also called a graphite electrode, and is widely used as a steelmaking electrode. Examples of the extruded graphite that can be used include HLM manufactured by SGL Carbon AG, PSG332 manufactured by SEC Carbon Limited, and the like.

The molded graphite is obtained by embossing raw material powder made up of coke and a binder, then, firing and graphitizing the raw material powder. Since the molded graphite is uniaxially pressurized, the hexagonal net surfaces of graphite crystals are liable to be arranged on a surface that is at a right angle to the pressure direction, and the intrinsic resistance and thermal expansion coefficient become highest in the pressure direction.

Generally, since fine raw material powder can be used for the isotropic graphite and the molded graphite compared to the extruded graphite, a material having a fine structure and a high strength can be easily obtained. Furthermore, since the variation in block and direction property of the intrinsic resistance are small in the isotropic graphite, when used as a heater, a high strength can be obtained so that the errors in total resistance, which is caused when manufacturing the heater, can be decreased.

In addition, any coke can be used as the coke, which is a raw material of the graphite. The coke may be any of needle coke and amorphous coke, and may be any of petroleum-based coke and coal-based coke.

A power supply supplied to the graphite heater is not particularly limited, and may be a direct-current power supply or an alternative-current power supply. In the case of the alternative-current power supply, the power supply may be a single-phase power supply or a three-phase power supply.

A support portion 11 of the embodiments of the present invention supports a load applied from a main body portion 10 of the graphite heater. The main body portion 11 of the embodiments of the present invention may not only support a load of the main body portion 10, but also have a function of supplying an electric current to a graphite heater 100. In addition, the support portion 11 that only supports a load and the support portion 11 that supplies an electric current and supports a load may coexist.

In the case of a direct-current or single-phase power supply, the graphite heater can be configured as long as two sets of the support portion 11 and a terminal portion 4 are provided. Furthermore, the number of the sets of the support portion 11 and the terminal portion 4 are not limited to two, and a larger number of the sets may be used. In a case in which four support portions 11 are used and disposed at approximately 90° intervals, the support portions may be connected to power supplies having mutually different polarities respectively, or a power supply may be connected only to mutually facing support portions 11, and the remaining support portions 11 may simply support a load of the graphite heater 100.

In a case in which a three-phase alternative-current power supply is connected, three support portions 11 are desirably used. When the power supply is connected to the three support portions 11, the delta connection of the graphite heater 100 is possible, an electric power can be uniformly supplied to the tubular graphite heater 100, and heat can be uniformly generated.

The graphite heater 100 of the embodiments of the present invention has a plurality of the terminal portions 4 extending outward along the central axis a. The expression “extending outward along the central axis a” refers to the direction in which the tube extends (the z1 direction or the z2 direction), and, for example, the tube is formed in a partially extending manner. The graphite heater 100 of the embodiments of the present invention has a plurality of the terminal portions 4. The plurality of the terminal portions 4 may extend in the same direction (the z1 direction or the z2 direction) or extend in mutually different directions, but preferably extend in the same direction. When the terminal portions extend in the same direction, since the locations of the plurality of the terminal portions 4 in the z direction do not mutually deviate even when the graphite heater 100 is heated and thermally expanded, it becomes unnecessary to have a mechanism that negates thermal expansion in the z direction in a graphite heater installing portion of the apparatus. Therefore, the terminal portions 4 of the graphite heater can be easily supported.

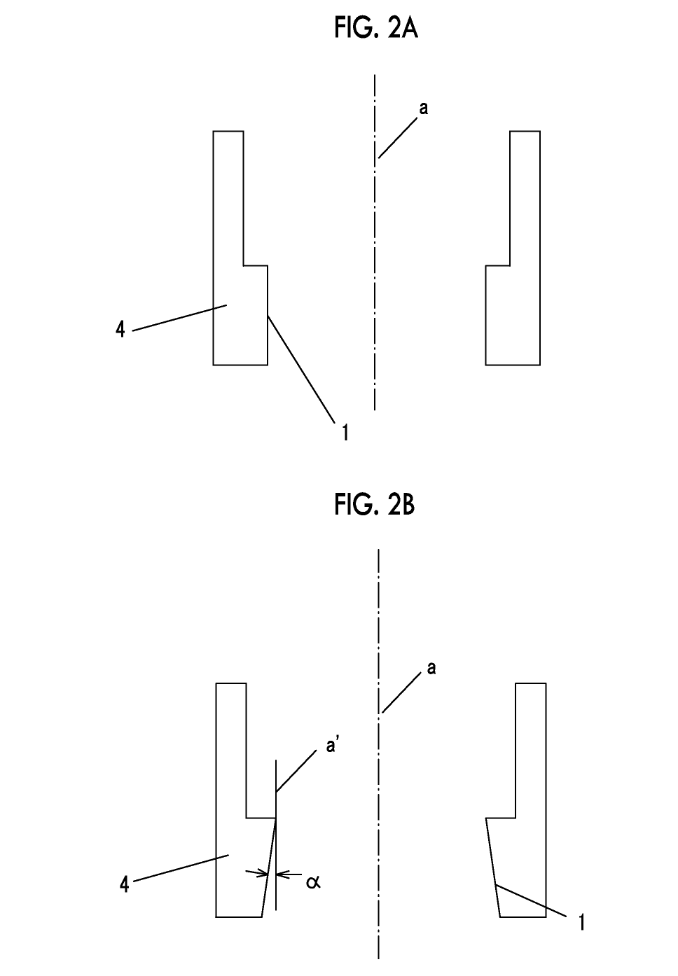

FIG. 2 illustrates the side views of the terminal portion 4, which schematically illustrate the positional relationship between the central axis a and a first planar surface 1 in an example of the graphite heater of the embodiments of the present invention. FIG. 2A illustrates a case in which the central axis a and the first planar surface 1 are in parallel with each other, in which the dashed-dotted line indicates the central axis a of the tubular graphite heater 100. FIG. 2B illustrates a case in which the central axis a and the first planar surface 1 intersect at an angle formed between the central axis a and the first planar surface 1 (a first angle) α, in which a′ indicates an auxiliary line for description that is parallel to the central axis.

The graphite heater of the embodiments of the present invention has the first planar surfaces 1 facing the central axis a side or the opposite side of the central axis a in the plurality of the terminal portions 4 extending outward along the central axis a. The first planar surface 1 is joined to a second planar surface 2 of the support portion 11 through a carbon-based adhesion layer 3. Since the first planar plane 1 faces the central axis a side or the opposite side of the central axis a, it is possible to freely increase the area by extending the terminal portions 4 along the central axis (in the z direction).

The fact that the first planar surface 1 faces the central axis side or the opposite side of the central axis indicates that the first angle α is small. A preferable first angle α is 10° or less, and a more preferable first angle is approximately 0°, that is, the first planar surface and the central axis are preferably substantially parallel to each other. When the first angle α is substantially 10° or less, the adhesion layer 3 having a sufficiently large area can be ensured in the thin terminal portion 4. Furthermore, when the first angle α is substantially 0° (substantially parallel), it is possible to obtain the adhesion layer 3 having a large area regardless of the thickness of the terminal portion 4. The adhesion layer 3 may be formed not only on the first planar surface 1 but also on the bottom surface of the terminal portion 4. It is possible to further increase the joining area between the main body portion 10 and the support portion 11.

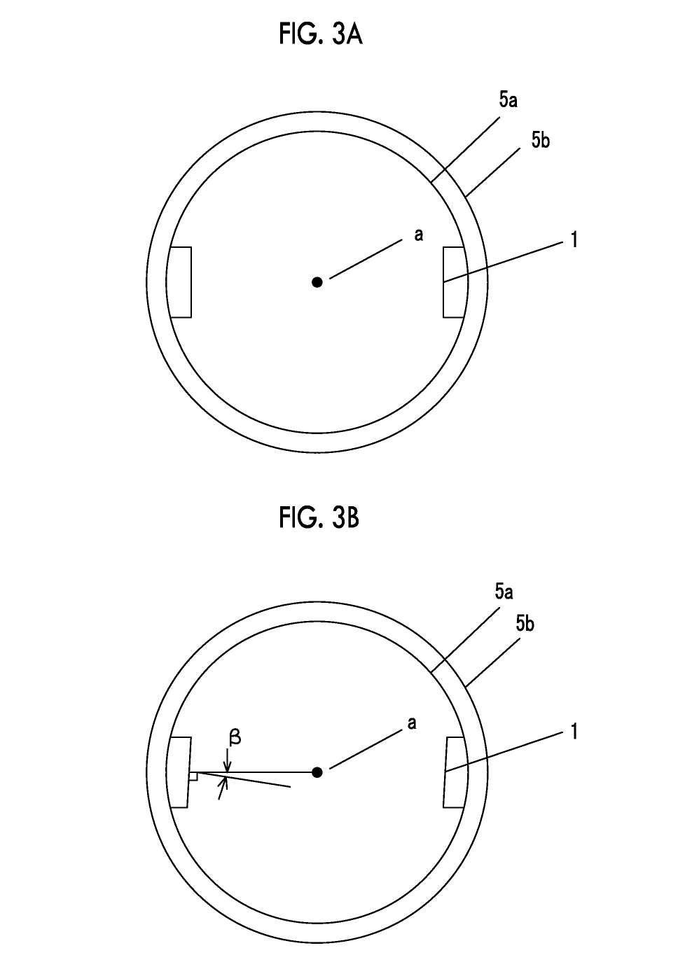

FIG. 3 illustrates the plan views schematically illustrating the positional relationship between the central axis a and the first planar surface 1 in an example of the graphite heater 100 of the embodiments of the present invention. The point in the center indicates the central axis a of the tubular graphite heater 100. FIG. 3A illustrates a case in which the distance between the first planar surface 1 and the central axis a becomes smallest in the middle of the first planar surface 1, that is, an angle formed between a line that connects the center of the first planar surface 1 and the central axis a and a normal line to the first plane surface 1 (second angle) β is 0°. FIG. 3B illustrates a case in which the second angle β is not 0°.

The distance between the first planar surface 1 and the central axis a of the embodiments of the present invention is preferably smallest in the middle of the first planar surface 1. The fact that the distance between the first planar surface 1 and the central axis a of the embodiments of the present invention becomes smallest in the middle of the first planar surface 1 indicates that the central axis a has a certain positional relationship with the front surface or rear surface of the first planar surface 1. In other words, it is illustrated that an angle formed between a line that connects the center of the first planar surface 1 and the central axis a and the normal line to the first plane surface 1 (second angle) β is substantially 0°. FIG. 2 illustrates a state in which the distance between the first planar surface 1 and the central axis a becomes smallest in the middle of the first planar surface 1. When the second angle β is a large value, and the first planar surface 1 faces horizontally, it becomes difficult to have a large adhesion layer 3.

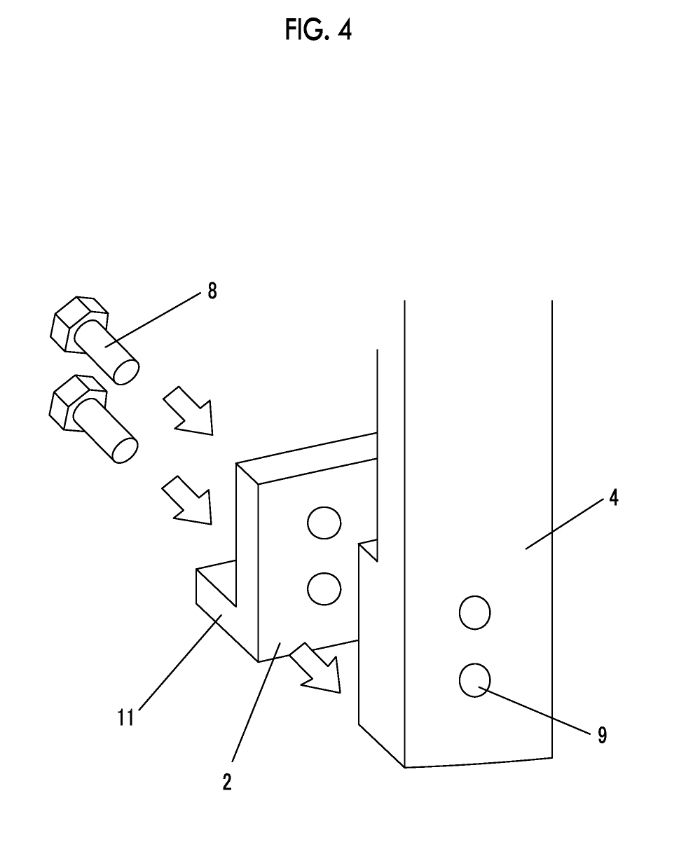

FIG. 4 illustrates an example of a joining method between the terminal portion 4 and the support portion 11. FIG. 4 illustrates a state in which the terminal portion 4 and the support portion 11 are not yet joined, and a carbon-based adhesive is coated on the first planar surface 1 or the second planar surface 2.

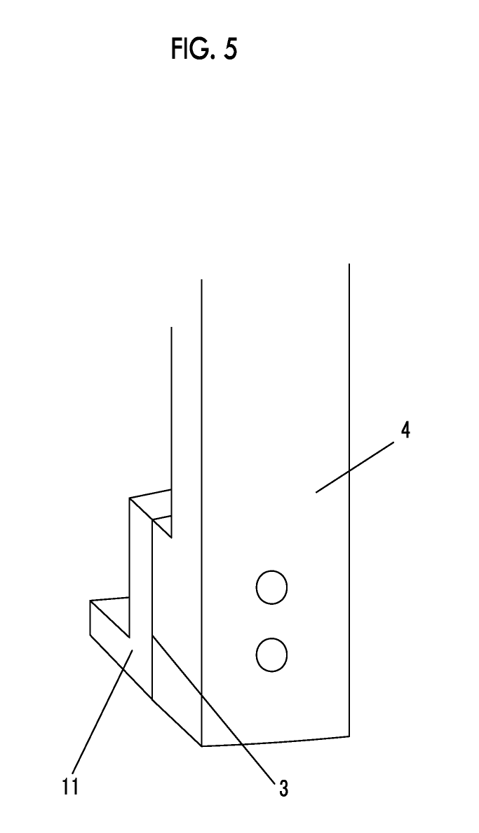

FIG. 5 illustrates a state in which the terminal portion 4 and the support portion 11 have been joined. In the state of FIG. 4, in which the terminal portion and the support portion are not yet joined, the carbon-based adhesive may be coated on both the first planar surface 1 and the second planar surface. The carbon-based adhesive is cured and fired so as to form the carbon adhesion layer 3 as described below. In FIG. 4, bolt holes 9 for connecting the support portion 11 and the terminal portion 4 are further formed in both the support portion 11 and the terminal portion 4. Bolts 8 made of carbon are screwed into the bolt holes 9. The bolts 8 may be inserted from any of the support portion side and the terminal portion side. The support portion 11 and the terminal portion 4 are tightened by providing male screws in any of the terminal portion 4 and the support portion 11 or further providing nuts, and using the male screws and the bolts or the bolts and the nuts.

The carbon-based adhesion layer 3 is made of graphite or carbon. The carbon-based adhesion layer 3 can be obtained by firing a carbon-based adhesive, and, since maintaining strength and conductive property even after firing, the carbon-based adhesion layer can be preferably used. Examples of the carbon-based adhesive that can be used include thermosetting resins, such as COPNA resin, phenol resins, furan resins and epoxy resins, and thermoplastic resins, such as pitch, polyethylene, polypropylene and polyvinyl alcohols. The COPNA resin is made of a polycyclic aromatic resin, a crosslinking agent made of two or more hydroxyl groups and an acid catalyst. Among the above, the COPNA resin can be preferably used since having favorable strength and conductive property.

The carbon-based adhesive forms the graphite or carbon adhesion layer 3 by firing a precursor of an organic substance. During firing, the volume of the organic substance decreases, and the volume of the adhesion layer 3 becomes smaller than that of the carbon-based adhesive. When the volume of the adhesion layer 3 decreases, the thick portion of the adhesion layer 3 is liable to shrink, and voids become liable to be generated in the thick portion. When voids are generated in the adhesion layer 3, the adhesion force becomes small, and the resistance becomes large. In such a case, when used in the graphite heater, the adhesion layer 3 is detached, or abnormal heat generation occurs in the adhesion layer 3.

In order to prevent the generation of voids in the adhesion layer 3, graphite powder or carbon powder may be added to the carbon-based adhesive as an aggregate. When an aggregate is added to the adhesive, it is possible to decrease the reduction of the volume and to prevent the generation of voids in the adhesion layer 3.

The terminal portion 4 of the embodiments of the present invention has the first planar surface 1, and the support portion 11 has the second planar surface 2. That is, the surfaces to be adhered are all configured to be planar surfaces.

In a case in which the joining portion between the terminal portion 4 and the support portion 11 is formed on a curved surface, machining errors are liable to be caused by the temperature and the like of a cutting substance and a processing machine, and thus cutting proceeds little by little using a blade such that recesses and protrusions are liable to be caused. In addition, in a case in which a surface to be adhered is a curved surface, even when the shapes of two adhesion surfaces are similarly processed, it is difficult to adhere the adhesion surfaces without voids by matching the recesses and protrusions on both surfaces during attaching.

For the above reasons, the variation in the thickness of the adhesive is caused on the curved surfaces to be adhered due to machining errors, recesses and protrusions on the surfaces, and deviation during attaching, the thick portion significantly shrinks during firing, and voids become liable to be generated in the adhesion layer 3.

In contrast to the above, the first planar surface 1 can be obtained by, for example, processing a graphite material into a tubular shape using a lathe, and then processing the material so as to form a planar surface in the machining center. Since the process of the first planar surface 1 does not need to be a fine process, it is possible to process the first planar surface using a blade having a large R or a blade having a linear blade edge. Therefore, a surface having a high accuracy and little unevenness can be easily obtained.

The second planar surface 2 of the support portion 11 can be processed, for example, through milling using a blade, using a planar grinding machine using a grind stone, or the like. Since it is not necessary to use a blade having a small R in any processes, recesses and protrusions are not easily generated on the processed surface, and a surface having a high accuracy and little unevenness can be easily obtained.

Since the first planar surface 1 and the second planar surface 2 are both planar surfaces, the embodiments of the present invention has characteristics that the embodiments of the present invention is not easily influenced by machining errors, recesses and protrusions are not easily generated on the surface, and the embodiments of the present invention is not easily influenced by deviation during attaching. Thereby, the variation in the thickness of the adhesive is not easily caused, and therefore it is possible to prevent voids from being easily generated in the adhesion layer 3. Therefore, the adhesion strength and conductive property of the adhesion layer 3 can be increased.

The embodiments of the present invention preferably has a plurality of the support portions 11 so that the support portions are rotationally symmetric around the central axis a. When the plurality of the support portions 11 are provided in a rotationally symmetric manner, since it is possible to make the resistance between the support portions the same, the variation of the heat generation in the graphite heater can be decreased.

The main body portion 10 of the graphite heater 100 of the embodiments of the present invention has a tubular shape. The tubular main body portion 10 has a heat generating portion 5 in which slits 7 are alternatively formed from the z1 direction and the z2 direction. The slits 7 are preferably formed throughout the circumference of the main body portion; however, since an electric current is divided into clockwise rotation and counterclockwise rotation at the terminal portion 4, and the methods of voltage drop are the same, the slits 7 may not be formed in the vicinity of the terminal portion 4.

In the graphite heater 100 of the embodiments of the present invention, since the total resistance of the graphite heater increases when the number of the slits 7 increases, and the total resistance of the graphite heater decreases when the number of the slits 7 decreases, it is possible to adjust the total resistance by increasing or decreasing the number of the slits 7.

In addition, the total resistance of the graphite heater 100 can be adjusted using the thickness of a tubular portion 6. The thickness of the tubular portion 6 can be adjusted in any of the inner diameter side and the outer shape side. In a case in which the total resistance of the graphite heater is adjusted after the processing of the slits 7, when the outer diameter side is processed with a center core therein, it is possible to easily process the outer diameter side, and to adjust the total resistance.

The minimum value of the distance between the first planar surface 1 and the central axis a of the embodiments of the present invention is desirably smaller than the radius of the inner surface of the heat generating portion 5a. That is, the center of the first planar surface 1 is located on the inside of the inner surface of the heat generating portion 5a. Herein, the first planar surface 1 faces the inside. Since the center of the first planar surface 1 is located on the inside of the inner surface of the heat generating portion 5, it is possible to sufficiently increase the thickness of the terminal portion 4. Therefore, since it is difficult to generate heat in the terminal portion 4, and the width of the adhesion layer 3 is easily increased, it is possible to increase the area of the adhesion layer 3 without significantly extending the terminal portion 4.

In the graphite heater 100 of the embodiments of the present invention, the support portion 11 and the main body portion are desirably further connected to each other using the bolts 8 made of carbon, which penetrate the adhesion layer 3. The bolts made of carbon may be graphite bolts or bolts made of a C/C composite. When the support portion 11 and the main body portion are connected using the bolts 8 made of carbon, not only are the support portion and the main body portion connected, but it is also possible to strongly hold a pressure in a firing process so as to make the carbon-based adhesive thin. The generation of voids can be prevented by carrying out firing while applying a pressure. Since voids are not easily generated, the adhesion strength and conductive property of the adhesion layer 3 can be increased.

The graphite heater of the embodiments of the present invention can be preferably used as a graphite heater used for a silicon single crystal pull-up apparatus. Since there is a need for a large-sized heater as the diameter of a silicon wafer increases such that the graphite heater for a silicon single crystal pull-up apparatus is used at a low voltage, a large electric current is made to flow in order to obtain a heat generation amount. This is because there is a demand for a high electric conductivity in the adhesion layer 3. In addition, since the graphite heater 100 of the embodiments of the present invention is manufactured through graphitizing, and the adhesion layer 3 is made of a carbon material, a metal material is not included. Graphite and the carbon material have a sublimation point of approximately 3600° C. or higher, the vapor pressure is extremely low, and therefore the graphite heater can be preferably used as a graphite heater for a silicon single crystal pull-up apparatus.

In Embodiment 1 of the invention, the graphite heater having two terminal portions has been described.

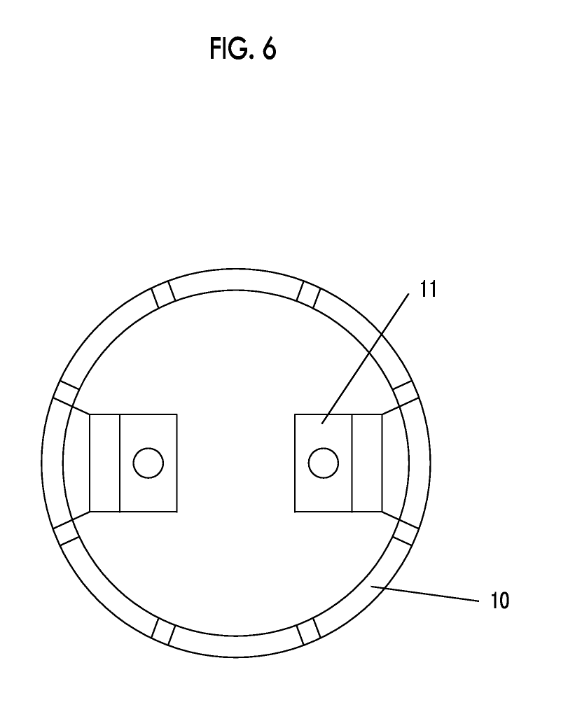

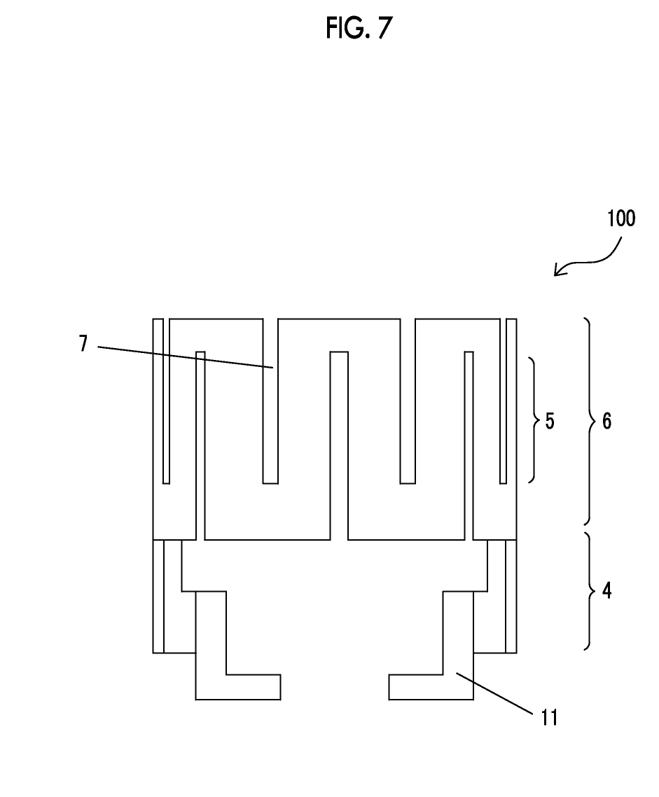

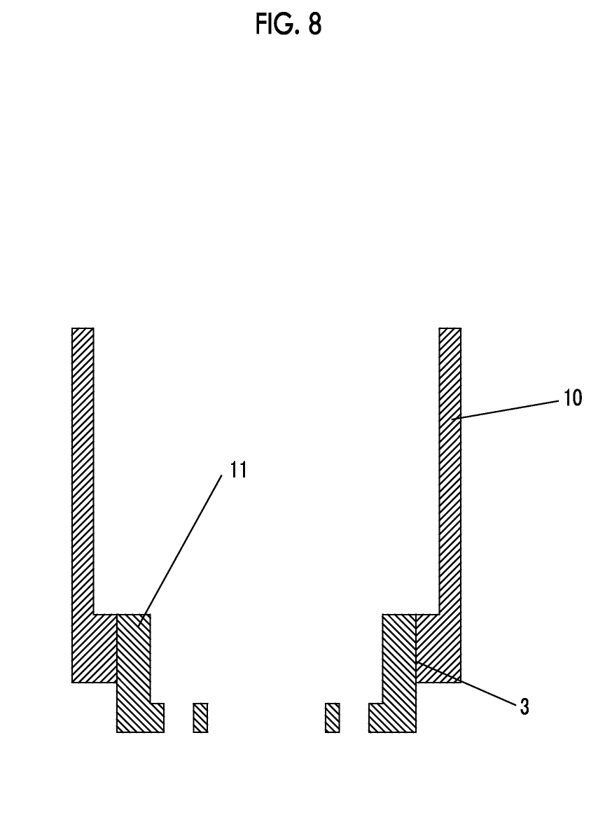

FIG. 6 illustrates a plan view of the graphite heater of Embodiment 1, FIG. 7 illustrates a front view of the graphite heater of Embodiment 1, and FIG. 8 illustrates a cross-sectional view of the graphite heater of Embodiment 1.

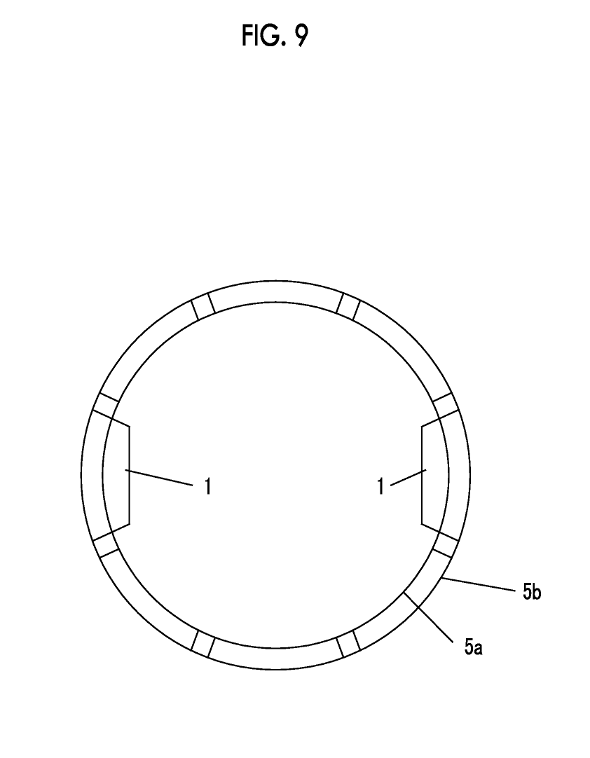

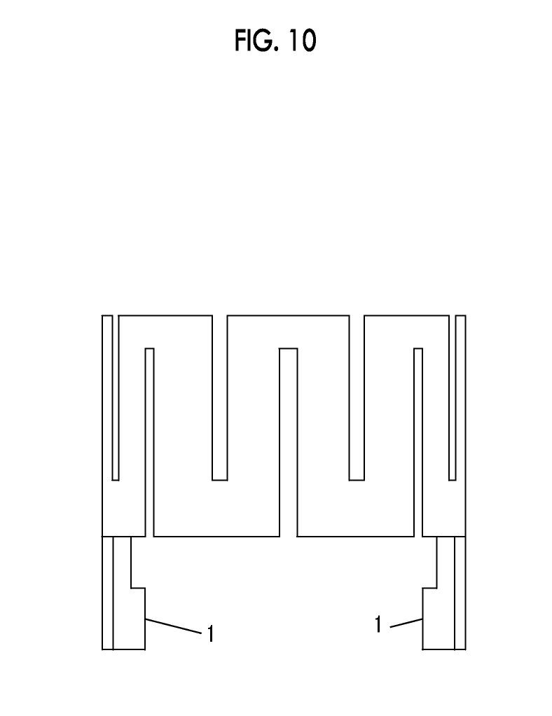

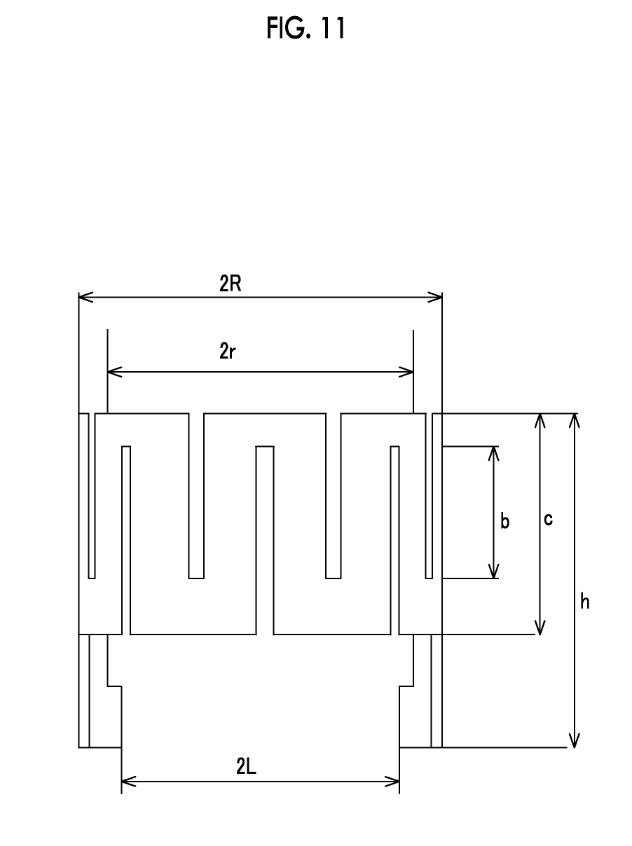

FIG. 9 illustrates a plan view of the main body of the graphite heater of Embodiment 1 of the invention, FIG. 10 illustrates a front view of the main body of the graphite heater of Embodiment 1 of the invention, and FIG. 11 illustrates an explanatory view illustrating the dimensions of the main body of the graphite heater of Embodiment 1 of the invention.

The outer diameter 2R of the tubular portion 6 of the graphite heater is approximately 1000 mm, the inner diameter 2r is approximately 950 mm, and both are the same as the outer diameter and inner diameter of the heat generating portion 5. The height h of the main body portion is approximately 800 mm, and the height c of the tubular portion is approximately 700 mm. The heat generation length b refers to the length of an area in the height of the main body portion, which the slits 7 extending from top and bottom both run, and is approximately 500 mm.

The material of the graphite heater is ET-10 manufactured by Ibiden Co., Ltd. Eight slits 7 are formed at equal intervals of 45 degrees from the bottom side, and six slits are formed at intervals of approximately 45° on the upper side. The slits 7 formed at the locations of the terminal portions 4 from the top may not be formed, and therefore only six slits may be formed from the top.

The first planar surface 1 facing the inside is formed in the terminal portion 4. The distance 2L between the first plane surfaces of two terminal portions 4 is approximately 800 mm. The terminal portions 4 have a mutually facing positional relationship (approximately 180° with respect to the central axis a).

The first planar surface 1 is parallel to the central axis a, and the distance between the first planar surface 1 and the central axis a becomes smallest at the center portion. That is, the central axis a is located on the front surface of the first planar surface 1.

The L-shaped support portions 11 are connected to the first planar surfaces 1 of the two terminal portions 4 through the carbon-based adhesion layers 3. Screw holes are provided in the terminal portion 4, and the terminal portion and the support portion are tightened using the graphite bolts 8 from the support portion side. A power supply is connected to the bottom end of the L-shaped support portion.

The carbon-based adhesion layer 3 is formed by carburizing a COPNA resin.

The graphite heater 100 of the embodiment is manufactured, for example, in the following order.

The main body portion 10 is prepared in the following manner. First, graphite is processed using a lathe, and is processed into a tubular shape having an inwardly-bent bottom. Next, the bottom side is processed using a machining center so as to form the terminal portion 4, and then the slits 7 are processed. Next, the second planar surface 2 of the support portion that has been shaped into an L letter is adhered to the first planar surface 1 using the carbon-based adhesive (COPNA resin).

The adhesion of the COPNA resin is carried out by heating the COPNA resin so as to decrease the viscosity. Since the viscosity is low, it is possible to make the COPNA resin thin by applying a pressure to the adhesive. The pressure may be applied using any method, and a pressure can be applied using the graphite bolts 8 that penetrate the adhesion layer 3. In the embodiment, since the adhesive is further cured and fired while applying a pressure using the bolts 8, it is possible to compress the adhesion layer 3 in accordance with the carburization shrinkage of the COPNA resin, and it is possible to obtain the adhesion layer 3 having favorable strength and electric conductivity, and no void.

As a specific adhering method of the COPNA resin, the main body portion 10 and the support portion 11 are heated in advance. The heating temperature is desirably approximately 40° C. to approximately 100° C. Next, the COPNA resin is coated on the first planar surface 1 or the second planar surface 2, and the planar surfaces are attached to each other. Since the COPNA resin has a high viscosity, the COPNA resin can be easily coated when heated to approximately 50° C. After the first planar surface 1 and the second planar surface 2 are attached to each other, a pressure is applied, and the adhesive is pulled and extended so as to be thin. At this time, air bubbles are discharged outside together with excess resin. Next, the adhesive is cured and fired while the pressure is applied. The pressure may be applied using a jig, such as a clamp, or may be applied by tightening holes formed in the main body portion 10 and the support portion 11 using the bolts 8. When tightened using the bolts 8, since the positioning accuracy increases so that the main body portion 10 and the support portion 11 thermal expand in the same manner during curing and firing, the tightening force is not easily changed even when heat is applied, and a compressive force can be maintained. In addition, since the bolts 8 are made of carbon, similarly to the heater, and the bolts are not softened, melted or modified due to heating, the bolts can be preferably used.

The attached planar surfaces are desirably cured under conditions of approximately 100° C. to approximately 200° C. for approximately 30 minutes or more. When cured under conditions of approximately 100° C. to approximately 200° C. for approximately 30 minutes or more, since the planar surfaces can be sufficiently cured under mild conditions, voids are not easily formed due to the generation of air bubbles in the curing process. Therefore, the adhesion layer 3 having favorable strength and electric conductivity can be obtained. Furthermore, the graphite heater is heated at approximately 2000° C. in a reducing atmosphere or an inert gas atmosphere, and the adhesion layer 3 is carburized or graphitized. Carburization or graphitization supplies a high electric conductivity to the adhesion layer 3.

The graphite heater 100 of the embodiment can be connected to a single-phase alternative-current or direct-current power supply.

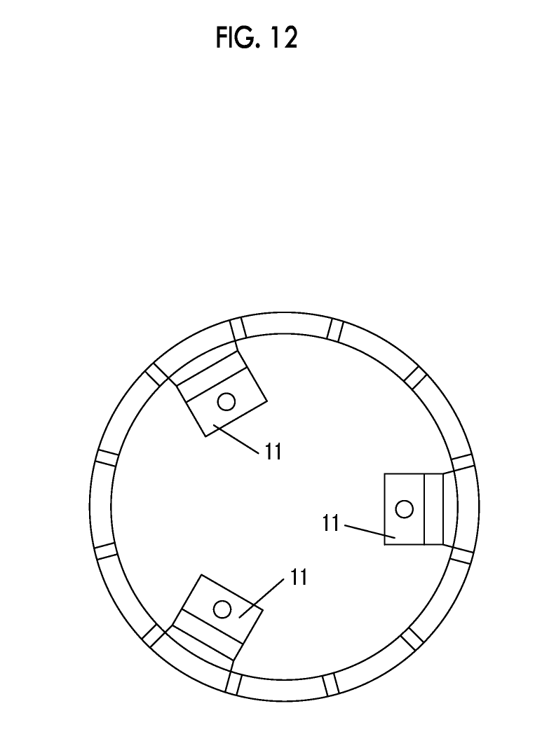

FIG. 12 describes a graphite heater having three terminal portions 4, which is a first modification example of Embodiment 1. The graphite heater of the present modification example can be used by connecting the graphite heater to a three-phase alternative-current power supply. In the graphite heater of the modification example, the three terminal portions 4 are connected to R, S and T phases through the support portions 11 respectively, thereby forming a delta connection.

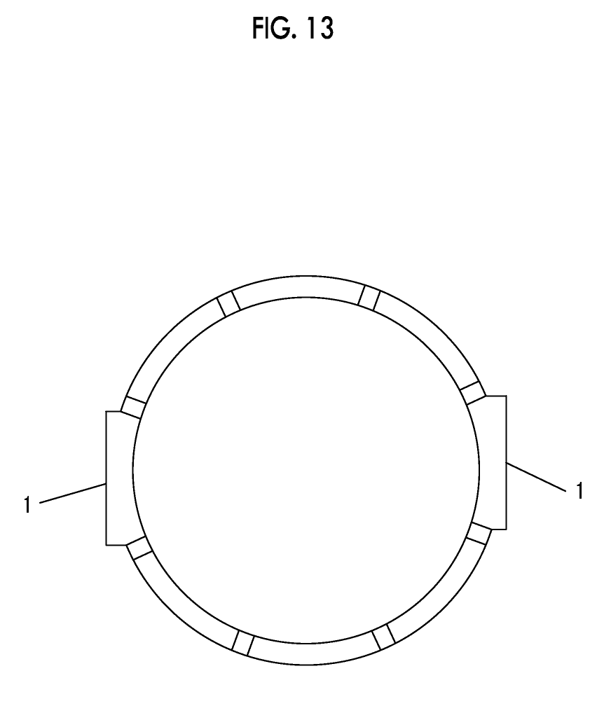

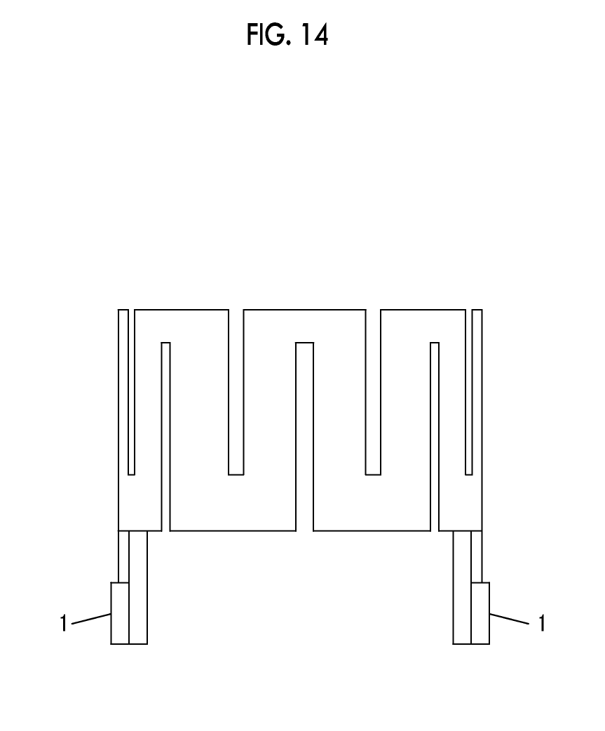

FIG. 13 illustrates a bottom surface view of a main body portion of a second modification example of Embodiment 1. FIG. 14 illustrates a front view of the main body portion of the second modification example of Embodiment 1. The second modification example of Embodiment 1 illustrates a graphite heater in which two terminal portions 4 are provided, and the first planar surface 1 of the terminal portion 4 faces the opposite side of the central axis a. In the modification example, the first planar surface 1 faces outside, and the support portion 11 is configured around the graphite heater through the adhesion layer 3.

Obviously, numerous modifications and variations of the present invention are possible in light of the above teachings. It is therefore to be understood that within the scope of the appended claims, the invention may be practiced otherwise than as specifically described herein.

1. A graphite heater comprising:
a main body comprising:
a tubular portion; and
a plurality of terminal portions extending outward along a central axis of the tubular portion, each of the plurality of terminal portions having a first planar surface facing the central axis or facing an opposite side of the central axis; and
a plurality of support portions each joined to each of the plurality of terminal portions, each of the plurality of support portions having a second planar surface, the first planar surface and the second planar surface being joined through a carbon-based adhesion layer.

2. The graphite heater according to claim 1,
wherein the plurality of the support portions are provided around the central axis as an axis of rotation symmetry.

3. The graphite heater according to claim 2,
wherein the first planar surface faces the central axis, and a distance between the first planar surface and the central axis is smallest at a center of the first planar surface.

4. The graphite heater according to claim 3,
wherein the tubular portion has a heat generating portion which has slits, and a minimum value of a distance between the first planar surface and the central axis is smaller than a radius of an inner surface of the heat generating portion.

5. The graphite heater according to claim 1,
wherein the support portions and the terminal portions are further connected using bolts which penetrate the carbon-based adhesion layer and are made of carbon.

6. The graphite heater according to claim 1, which is used in a silicon single crystal pull-up apparatus.
